(19) United States
(12) Patent Application Publication
(10) Pub. No.: US 2025/0374700 A1
(43) Pub. Date: Dec. 4, 2025

(54) STACK TYPE IMAGE SENSING DEVICE AND METHOD OF MANUFACTURING THE SAME

(71) Applicant: SK hynix Inc., Icheon-si (KR)

(72) Inventor: Han Seung LEE, Icheon-si (KR)

(21) Appl. No.: 18/913,729

(22) Filed: Oct. 11, 2024

(30) Foreign Application Priority Data
May 31, 2024 (KR) 10-2024-0071459

(51) Int. Cl. H01L 27/146

(52) U.S. Cl. CPC H10F 39/809; H10F 39/018; H10F 39/811

(57) ABSTRACT

Image sensing devices and methods of manufacturing image sensing devices are disclosed. In an embodiment, a method of manufacturing an image sensing device May include stacking a first structure that includes a first substrate, a first device layer, a first conductive pad, a first bonding layer, and a second structure that includes a second substrate, a second device layer, a second bonding layer by bonding the first bonding layer and the second bonding layer to each other to expose a back side of the first substrate, and etching the exposed back side of the first substrate by a partial thickness of a thickness of the first substrate to expose the first conductive pad in the first substrate.

### CROSS-REFERENCES TO RELATED APPLICATION

This patent document claims the priority and benefits of Korean application number 10-2024-0071459, filed on May 31, 2024, which is incorporated herein by reference in its entirety.

### TECHNICAL FIELD

The technology and implementations disclosed in this patent document relate to a stack type image sensing device and a method of manufacturing the same.

### BACKGROUND

Image sensing devices convert optical images into electrical signals. Examples of image sensing devices include CMOS image sensors (CISs) and charge-coupled devices (CCDs). Such image sensing devices are widely used in a variety of electronic applications, such as digital still cameras or cell phone camera applications.

### SUMMARY

The disclosed technology can be implemented in some example embodiments to provide a stack type image sensing device can improve its electrical characteristics.

The disclosed technology can be implemented in some example embodiments to provide a method of manufacturing the above-mentioned stack type image sensing device.

In example embodiments, a method of manufacturing an image sensing device may include stacking a first structure that includes a first substrate, a first device layer, a first conductive pad, a first bonding layer, and a second structure that includes a second substrate, a second device layer, a second bonding layer, by bonding the first bonding layer and the second bonding layer to each other to expose a back side of the first substrate, wherein the first device layer is formed on a front side of the first substrate where the front side and the back side are on two opposite sides of the first substrate, the first conductive pad extends from an upper portion of the first device layer toward the first substrate, and the first bonding layer is formed over the first conductive pad and the first device layer, wherein the second device layer is formed on the second substrate, and the second bonding layer is formed on an upper surface of the second device layer, and etching the exposed back side of the first substrate by a partial thickness of a thickness of the first substrate to expose the first conductive pad in the first substrate.

In example embodiments, a method of manufacturing an image sensing device may include forming a first device layer on a front side of a first substrate which includes a back side that is opposite to the front side, forming a preliminary open region in the first device layer and the first substrate, forming a first conductive pad on a bottom portion of the preliminary open region in the first substrate, a first sidewall portion connected to the bottom portion, and an outer portion of the preliminary open region connected with the first sidewall portion, forming a first bonding layer including a first bonding pad in contact with the first conductive pad located on the first device layer, forming a second device layer, and a second bonding layer that includes a second bonding pad corresponding to the first bonding pad that are sequentially stacked on a second substrate, bonding the first bonding layer to the second bonding layer to bond the first substrate to the second substrate, and etching the back side of the first substrate to expose the first conductive pad located at the bottom portion of the preliminary open region while bonding the first substrate and the second substrate to each other.

In example embodiments, a stack type image sensing device may include a first structure including a first substrate, an image device layer formed under the first substrate, and a first bonding layer including a plurality of first bonding pads under the image device layer, a second structure including a second bonding layer including a plurality of second bonding pads bonded to the plurality of first bonding pads of the first structure, a logic circuit layer positioned under the second bonding layer, and a second substrate positioned under the logic circuit layer, and a first conductive pad including a first horizontal extending portion spaced apart from a front side of the first substrate to a selected depth, a vertical extending portion extending from the first horizontal extending portion to a lower surface of the image device layer, and a second horizontal extending portion extending from the vertical extending portion by a set length along a lower surface of the image device layer, wherein the second horizontal extending portion of the first conductive pad is in contact with a selected first bonding pad that is selected from the plurality of first bonding pads.

In example embodiments, a method of manufacturing a stack type image sensing device may including preparing a first structure. The first structure may include a first substrate, a first device layer formed on a front side of the first substrate, a first conductive pad extending from an upper surface of the first device layer into the first substrate, and a first bonding layer formed on the first conductive pad and the first device layer. The method of manufacturing a stack type image sensing device may also include preparing a second structure. The second structure may include a second substrate, a second device layer formed on a front side of the second substrate, and a second bonding layer formed on the second device layer. The first structure and the second structure may be stacked by bonding the first bonding layer to the second bonding layer to expose a back side of the first substrate. The exposed back side of the first substrate may be partially etched by a thickness of the first substrate thickness to open the first conductive pad in the first substrate.

In example embodiments, a first substrate including a front side and a back side may be provided. A first device layer may be formed on the front side of the first substrate. A preliminary open region may be formed in the first device layer and the first substrate. A first conductive pad may be formed on a bottom portion of the preliminary open region located in the first substrate, one sidewall connected to the bottom portion, and the first device layer connected to the one sidewall and corresponding to an outer portion of the preliminary open region. A first bonding layer, which may include a first bonding pad contacting the first conductive pad on the first device layer, may be formed. A second substrate having a front side and a back side may be prepared. The second substrate may include a second device layer and a second bonding pad corresponding to the first bonding pad sequentially stacked on the front side. The first bonding layer and the second device layer may be bonded to each other to bond the first substrate to the second substrate. With the first substrate and the second substrate bonded, the back side of the first substrate may be etched to open the first conductive pad on the bottom portion of the preliminary open region.

In example embodiments, a stack type image sensing device may include a first structure, a second structure bonded to the first structure and a first conductive pad. The first structure may include a first substrate, an image device layer formed under the first substrate, and a plurality of first bonding pads positioned under the image device layer. The second structure may include a second bonding layer including a plurality of second bonding pads bonded to the plurality of first bonding pads of the first structure, a logic circuit layer positioned under the second bonding layer, and a second substrate positioned under the logic circuit layer. The first conductive pad may include a first horizontal extending portion formed at a location spaced apart from an upper surface of the first substrate to a selected depth, a vertical extending portion extending from one end of the first horizontal extending portion to a lower surface of the image device layer, and a second horizontal extending portion extending from one end of the vertical extending portion along the lower surface of the image device layer by a predetermined length. The second horizontal extending portion of the first conductive pad may make contact with any one of the plurality of first bonding pads. The selected depth may be from about 15% to about 60% of a thickness of the first substrate.

In example embodiments, before bonding the first structure including the image elements to the second structure including the logic circuits, the first conductive pad may be formed in the first structure. The first conductive pad may be formed to extend from the upper surface of the first structure into the first substrate including the first structure. The bonding pad of the first structure may be formed to be in direct contact with the conductive pad on the first structure.

By exposing the first conductive pad in the first substrate after bonding the first structure with the first conductive pad to the second structure, an etched amount of the first structure for exposing the first conductive pad may be beneficially reduced. Accordingly, an etch damage that would have been caused while exposing the pad may be prevented and the thickness uniformity of the pad may be improved.

Furthermore, since the first conductive pad formed on the first structure and the bonding pad in which a hybrid bonding is performed are in direct contact, a wiring resistance may be reduced.

### BRIEF DESCRIPTION OF THE DRAWINGS

The above and another aspects, features and advantages of the subject matter of the present disclosure will be more easily understood from the following detailed description taken in conjunction with the accompanying drawings.

FIG. 1 is a perspective view illustrating a stack type image sensing device based on some example embodiments.

FIG. 2 is a flow chart illustrating a method of manufacturing a stack type image sensing device based on some example embodiments.

FIGS. 3 to 10 are cross-sectional views illustrating a method of manufacturing a stack type image sensing device based on some example embodiments.

### DETAILED DESCRIPTION

In some embodiments discussed in this patent document, the term “configured” can be used to indicate a size, shape, material composition, orientation, and/or arrangement of a structure and/or an apparatus that facilitates the operation of one or more of the structure and the apparatus in a pre-determined way.

In some embodiments discussed in this patent document, the terms “vertical,” “longitudinal,” “horizontal,” and “lateral” can be used differently depending on the reference point of a structure. For example, a “horizontal” or “lateral” direction is a direction that is substantially parallel to a major plane of the structure, while a “vertical” or “longitudinal” direction is a direction that is substantially perpendicular to the major plane of the structure. In some embodiments, the major plane of the structure is defined by a surface of the structure having a relatively large area compared to other surfaces of the structure. With reference to the figures, a “horizontal” or “lateral” direction may be perpendicular to Z-axis, and may be parallel to X-axis and/or parallel to Y-axis; and a “vertical” or “longitudinal” direction may be parallel to Z-axis, may be perpendicular to X-axis, and may be perpendicular to Y-axis.

In some embodiments discussed in this patent document, spatially relative terms, such as “beneath,” “below,” “bottom,” “above,” “upper,” “top,” “front,” “rear,” “left,” “right,” etc., may be used to facilitate the description of the relationship between different elements or the relationship between different features as illustrated in the figures. In some embodiments, the spatially relative terms can be used to encompass different orientations of structures in addition to the orientation depicted in the figures. For example, if structures in the figures are inverted, the corresponding structures described as disposed “below” or “beneath” or “under” or “on bottom of” other structures can be disposed “above” or “on top of” the other structures.

In some embodiments discussed in this patent document, a front side, top surface, or first surface may mean a surface located at the top of a substrate or layer, and a bottom surface, bottom surface, or other surface may mean a surface located at the bottom of a substrate or any layer.

In some embodiments discussed in this patent document, the term “resultant” may be construed to include all layers formed on the substrate.

In some embodiments discussed in this patent document, the expression “electrically connected” may be used to include both direct and indirect connections. In some embodiments discussed in this patent document, the expression “contact” may mean that different components are directly connected.

Image sensing devices may be classified into back side illumination (BSI) type image sensing devices and front side illumination (FSI) type image sensing devices, depending on the position of the illumination light. Furthermore, to increase the pixel count in an image sensing device, stack type image sensing devices, which integrate the pixel array and logic circuit different substrates, can be used.

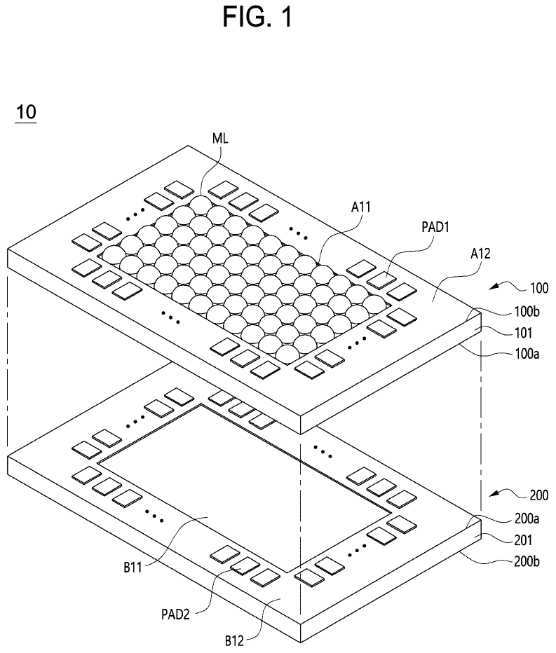

FIG. 1 is a perspective view illustrating a stack type image sensing device based on some example embodiments. This image sensing device is based on stacking of two different structures formed on separate substrates that support various components of the image sensing device. Specifically, this design separates various components of the image sensing device into a first group of components formed on a first substrate and a second group of components formed on a separate, second substrate and provides a stack type configuration by stacking the two substrates over each other to properly connect the 2 groups of components that are separately formed on the first and second substrates. Such stacking of different structures formed on different substrates provide certain benefits and advantages in the fabrication of the components and the final imaging device and in the final formed circuitry structures of the final imaging device.

Referring to FIG. 1, a stack type image sensing device 10 may include a first structure 100 and a second structure 200.

The first structure 100 may include a front side 100a and a back side 100b that are two opposite sides of the first structure 100. The first structure 100 may be disposed or stacked over the second structure 200 such that the front side 100a of the first structure 100 may face the second structure 200. The first structure 100 may include a pixel array region A11 and a first pad region A12. In some implementations, the term “pad” or “pad region” can be used to indicate a structure that serves the role of electrically connecting internal circuits disposed in a semiconductor to external circuits to transmit signals or supply power.

The pixel array region A11 may include a plurality of rows, a plurality of columns and a plurality of unit pixels PXs. Each of the unit pixels PXs may include a photodetector (not shown), at least one pixel transistor (not shown), a color filter (not shown) and a micro-lens ML.

The first pad region A12 may be positioned at a periphery of the pixel array region A11. A plurality of first conductive pads PAD1 may be arranged in the first pad region A12 at a set interval. Although not shown in the drawings, a plurality of first bonding pads may be arranged in the first pad region A12 on the front side 100a of the first structure 100. Each of the plurality of first bonding pads may be in direct contact with the plurality of first conductive pads PAD1.

The plurality of first conductive pads PAD1 may be electrically connected to external terminals (not shown), such as wires. Accordingly, the first pad region A12 may further include a pad opening region (not shown) configured to open each of the plurality of first conductive pads PAD1.

The second structure 200 may include a front side 200a and a back side 200b that are on two opposite sides of the second structure 200. For example, the front side 200a of the second structure 200 and the front side 100a of the first structure 100 may be arranged to face each other. The second structure 200 may include a logic circuit region B11 and a second pad region B12 that are coupled to responding components on the first structure 200 for the stack type image sensing device.

The logic circuit region B11 may correspond, for example, to the pixel array region A11. The logic circuit region B11 may include a circuit block configured to generate signals for controlling operations of the unit pixels and a circuit block configured to sense images, such as a row driver, a correlated double sampling circuit, an analog-to-digital converter, an output buffer, a column driver and a timing controller.

The second pad region B12 may be disposed on a periphery of the logic circuit region B11. A plurality of second conductive pads PAD2 may be arranged in the second pad region B12. The plurality of second conductive pads PAD2 may include, for example, second bonding pads to be hybrid-bonded with the first bonding pads PAD1. In example embodiments, the plurality of first conductive pads PAD1 and the plurality of second conductive pads PAD2 may be arranged to correspond to each other. The corresponding first conductive pad PAD1 and second conductive pad PAD2 may be electrically connected with each other in various ways.

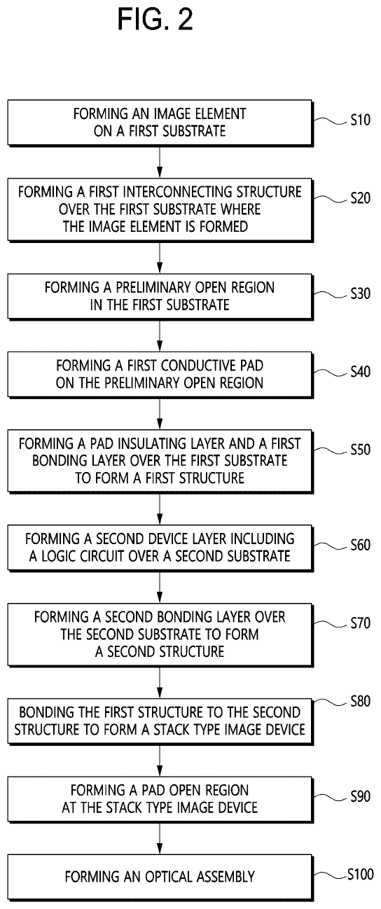

FIG. 2 is a flow chart illustrating a method of manufacturing a stack type image sensing device based on some example embodiments. FIGS. 3 to 10 are cross-sectional views illustrating a method of manufacturing a stack type image sensing device based on some example embodiments.

Referring to FIGS. 2 and 3, a first substrate 101 for forming the first structure 100 may be prepared. An image element may be formed on the first substrate 101 (S10). For example, the first substrate 101 may include silicon, single crystal silicon, germanium, silicon-germanium, and other semiconductor materials. Furthermore, the first substrate 101 may include, for example, dopants having a first conductivity. The first substrate 101 may include a front side 101a and a back side 101b facing the front side 101a. The first substrate 101 may include a pixel array region A11 where the pixels are arranged, as described above, and a first pad region A12 where first conductive pads are arranged.

A plurality of photodetectors 110 as the image element may be formed in the first substrate 101 corresponding to the pixel array region A11. For example, the plurality of photodetectors 110 may include dopants having a second conductivity. The second conductivity may be opposite to the first conductivity. A PN junction may be generated between the first substrate 101 including the first conductivity and the photodetector 110 including the second conductivity. For example, the photodetector 110 may be referred to as a photodiode. The photodetector 110 may be formed by selectively implanting the second conductive dopants towards the front side 101a of the first substrate 101. The plurality of photodetectors 110 may be spaced apart from each other in a matrix form. However, it will be obvious that the structure of the pixel array region A11 is only an example and may be varied. In some implementations, a photodetector may detect incident light to generate electrical charge representing the detected incident light. Such a photodetector may be implemented in various configurations, including, for example, a photodiode, a phototransistor, or a photogate.

Further, a floating diffusion 120 as the image element may be formed, respectively, in the pixel array region A11 of the first substrate 101. The floating diffusion 120 may include, for example, a doping region with the second conductivity. The floating diffusion 120 may be positioned adjacent to the front side 101a of the first substrate 101. For example, the floating diffusion 120 may have a higher doping concentration than that of the photodetector 110.

A plurality of transfer transistors 130 and a plurality of pixel transistors 135 as the image element may be formed in the pixel array region A11 of the first substrate 101. The plurality of transfer transistors 130 and the plurality of pixel transistors 135 may be located on the front side 101a of the first substrate 101. Each of the plurality of transfer transistors 130 may be positioned between the photodetector 110 and the floating diffusion 120. Each of the pixel transistors 135 may be disposed at an edge of the photodetector 110. In example embodiments, the transfer transistors 130 may have a buried gate structure. For example, the pixel transistors 135 may have a planar gate structure.

Referring to FIGS. 2 and 3, a first interconnecting structure 140 may be formed over the first substrate 101 where the image element is formed (S20). The first interconnecting structure 140 may be positioned over the front side 101a of the first substrate 101. The first interconnecting structure 140 may electrically connect the plurality of photodetectors 110, the plurality of floating diffusions (floating diffusion regions) 120, the plurality of transfer transistors 130, and the plurality of pixel transistors 135 with each other to form a first device layer DL1 including a plurality of pixels, that is, an image device layer corresponding to the pixel array region. The first interconnecting structure 140 may electrically connect the image elements to the first bonding pads that will be formed later. Further, the first interconnecting structure 140 may electrically connect the image elements to the first conductive pads that will be formed thereafter.

The first interconnecting structure 140 may be obtained by performing the following set of operations: forming an interlayer insulating layer 142; forming a vertical wiring layer 144 in the interlayer insulating layer 142; and forming a horizontal wiring layer 146 on the interlayer insulating layer 142.

The interlayer insulating layer 142 may electrically isolate between the plurality of transfer transistors 130 and the plurality of pixel transistors 135 and the horizontal wiring layer 144. The interlayer insulating layer 142 may electrically isolate the horizontal wiring layers 146 located below the interlayer insulating layer 142 and the horizontal wiring layers 146 located above the interlayer insulating layer 142. The interlayer insulating layer 142 may include at least one of a low-k insulation layer, a planarizing layer, or an etch stopper. For example, the vertical wiring layer 144 may be formed to penetrate the at least one interlayer insulating layer 142. The vertical wiring layer 144 may connect the horizontal wiring layer 146 to each of electrodes of the transfer transistor 130, and may connect the horizontal wiring layer 146 to each of electrodes of the pixel transistor 135. Furthermore, the vertical wiring layer 144 may electrically connect the horizontal wiring layer 146, which may be located at different heights, to the interlayer insulation layer 142 between the horizontal wiring layers 146. The vertical wiring layers 144 may also be referred to as vias or plugs. The horizontal wiring layers 146 may be electrically connected to the vertical wiring layer 144. The horizontal wiring layers 146 may transmit signals along with the vertical wiring layer 144.

For example, a first protective layer 147 may be further formed on the first interconnecting structure 140. The first protective layer 147 may include, for example, an insulating material. In some cases, the first protective layer 147 may be a part of the insulating interlayer 142.

In example embodiments, the first interconnecting structure 140 may also be provided on the first pad region A12. A gap between the vertical and horizontal wiring layers 144 and 146 of the first interconnecting structure 140 on the first pad region A12 may be wider than a gap between the vertical and horizontal wiring layers 146 of the first interconnecting structure 140 in the pixel array region A11.

A mask pattern M may be formed on the first interconnecting structure 140 in the first pad region A12 to define a region where the first conductive pad may be to be formed.

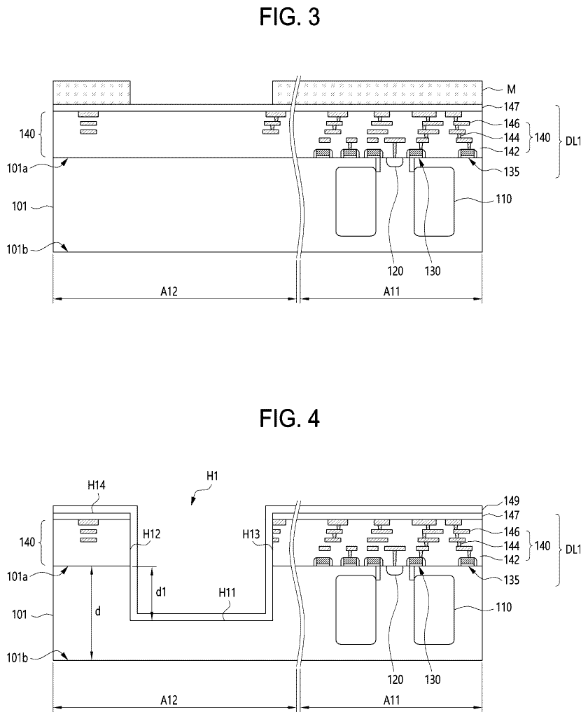

Referring to FIGS. 2 and 4, a preliminary open region H1 may be formed in the first substrate 101 (S30). In some implementations, the preliminary open region H1 may be formed in the first interconnecting structure 140 and the first substrate 101 corresponding to the first pad region A12.

For example, the first interconnecting structure 140 may be etched using the mask pattern M (see FIG. 3) to expose the front side 101a of the first substrate 101. Using the mask pattern M, the exposed front side 101a of the first substrate 101 may be etched to a first depth d1 to form the preliminary open region H1 in the first interconnecting structure 140 and the first substrate 101.

The first depth d1 may range from about 40% to about 85% of a thickness d of the first substrate 101. In example embodiments, when the first substrate 101 has a thickness of about 7 μm, the preliminary open region H1 may extend from the front side 101a of the first substrate 101 to a depth of about 3 μm to about 6 μm. The depth of the preliminary open region H1 may be a sum of a thickness of the first interconnecting structure 140 and a thickness d1 of about 40% to about 85% of the thickness d of the first substrate 101.

The preliminary open region H1 may be formed using at least one etchant. For example, the preliminary open region H1 may be formed using a dry etching process using plasma or a wet etching process. After forming the preliminary open region H1, the mask pattern M may then be removed. In some embodiments of the disclosed technology, the preliminary open region H1 may be formed by etching of the first interconnecting structure 140 and a partial thickness of the first substrate 101, thereby reducing damage caused by etching process, compared to etching the entire thickness of the first substrate 101 and the first interconnecting structure 140.

In some embodiments of the disclosed technology, a bottom portion H11 of the preliminary open region H1 may be located in the first substrate 101. First and second sidewall portions H12 and H13 of the preliminary open region H1 may extend from edges of the bottom portion H11 toward an upper surface H14 of the first interconnecting structure 140. Accordingly, the first substrate 101 and the first interconnecting structure 140 may be exposed by the first and second sidewall portions H12 and H13 of the preliminary open region H1. In some embodiments of the disclosed technology, the upper surface H14 of the first interconnecting structure 140 may correspond to an outer portion connected to any one of the first and second sidewall portions H12 and H13 of the preliminary open region H1.

A second protective layer 149 may be formed along the bottom portion H11 and

the first and second sidewall portions H12 and H13 of the preliminary open region H1. For example, the second protective layer 149 may include an insulating material. The second protective layer 149 may protect the first interconnecting structure 140 and the first substrate 101 exposed through the preliminary open region H1. While only one preliminary open region H1 is shown for ease of explanation, the preliminary open region H1 may be formed at each of regions where first conductive pads to be formed on the first substrate 101.

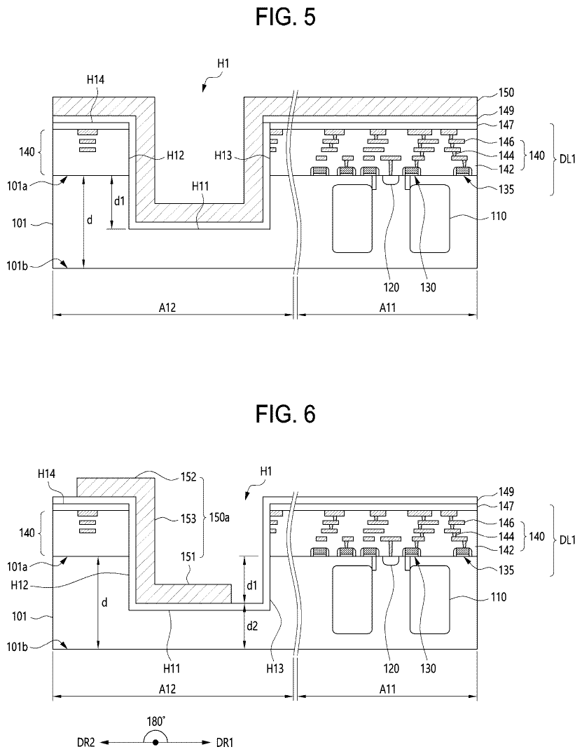

Referring to FIG. 5, a pad metal layer 150 may be formed over the second protective layer 149. The pad metal layer 150 may be formed with a conformal thickness over the second protective layer 149. In example embodiments, the pad metal layer 150 may be formed at a thickness of about 1.0 μm to about 1.5 μm, but is not limited thereto. For example, the pad metal layer 150 may include at least one of aluminum (Al) and copper (Cu).

Referring to FIGS. 2 and 6, a first conductive pad 150a may be formed on a selected portion of the preliminary open region H1 (S40). The first conductive pad 150a may be formed by etching a predetermined portion of the pad metal layer 150.

In example embodiments, the first pad metal layer 150 may be etched so as to the first pad meta layer 150 may remain on the bottom portion H11 of the preliminary open region H1, the first sidewall portion H12 of the preliminary open region H1 and the outer portion H14 of the preliminary open region H1 connected to the first sidewall portion H12 to form the first conductive pad 150a in the preliminary open region H1.

Accordingly, the first conductive pad 150a may be formed to include a first horizontal extending portion 151 positioned at the bottom portion H11 of the preliminary open region H1, a second horizontal extending portion 152 positioned at the outer portion H14 of the preliminary open region H1, and a vertical extending portion 153 positioned at the sidewall portion H12 of the preliminary open region H1 to connect the first and second horizontal extending portions 151 and 152 with each other. The first horizontal extending portion 151 and the second horizontal extending portion 152 may extend in a direction substantially parallel to the front side 101a or the back side 101b of the first substrate 101, respectively. The first horizontal extending portion 151 may extend in a first horizontal direction DR1. The second horizontal extending portion 152 may extend along a second horizontal direction DR2 having a 180° difference from the first horizontal direction DR1.

Further, if thicknesses of the first and second protective layers 147 and 149 may be negligible relative to the thickness of the first interconnecting structure 140 and the thickness d of the first substrate 101, the first horizontal extending portion 151 may be spaced apart from the front side 101a of the first substrate 101 by a first depth d1 and from the back side 101b of the first substrate 101 by a second depth d2 (e.g., d2 is d-d1). For example, the second depth D2 may be about 15% to about 40% of the thickness d of the first substrate 101.

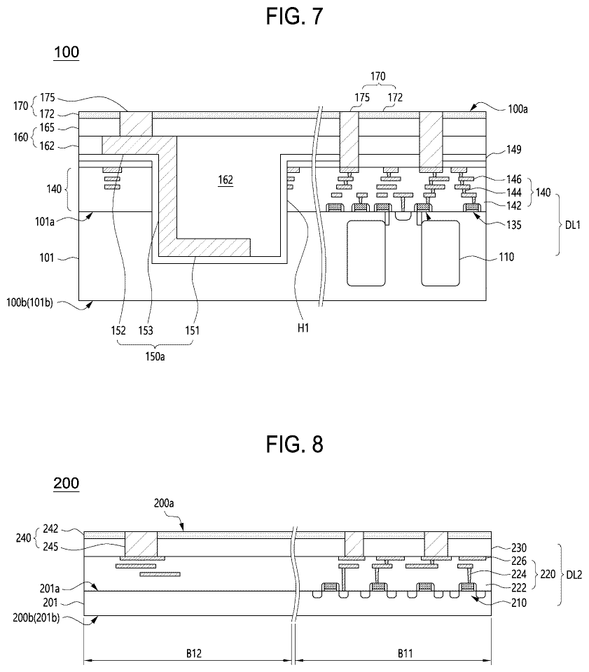

Referring to FIGS. 2 and 7, a pad insulating layer 160 and a first bonding layer 170 may be formed over the first substrate 101 with the first conductive pad 150a to form the first structure 100 (S50).

In some embodiments of the disclosed technology, the pad insulating layer 160 may include a first insulation layer 162 for filling the preliminary open region H1. For example, the first insulating layer 162 may be formed on the first conductive pad 150a to have a thickness for filing the preliminary open region H1. Subsequently, the first insulating layer 162 may be planarized to expose the second horizontal extending portion 152 of the first conductive pad 150a. For example, the first insulation layer 162 may include an insulating material having a gap-filling characteristic.

The pad insulating layer 160 may further include a second insulation layer 165 formed on the first insulation layer 162. The second insulation layer 165 may be interposed between the first insulation layer 162, which has a gap-filling function, and the first bonding layer 170 to be formed later. The second insulation layer 165 may serve as a buffer layer and an adhesive layer. In some implementations, the second insulation layer 165 may be omitted.

The first bonding layer 170 may be formed on the pad insulating layer 160. The first bonding layer 170 may include a first bonding insulation layer 172, and a plurality of first bonding pads 175 in the first bonding insulation layer 172.

In example embodiments, the first bonding insulation layer 172 may include at least one insulation layer. For example, the first bonding insulation layer 170 may include at least one of a silicon oxide layer (SiO2), a silicon nitride layer (Si3N4), a silicon nitride layer (SiON), a silicon carbide layer (SiC) and a silicon carbon nitride layer (SiCN).

The first bonding insulation layer 172 and the pad insulating layer 160 may be etched to form first bonding holes (not shown), such that selected portions of the horizontal wiring layers 146 and a selected portion of the first conductive pad 150a are exposed. A first bonding metal layer may be formed on the first bonding insulation layer 172 to fill the first bonding holes with the first bonding metal layer. For example, the first bonding metal layer may include copper (Cu). A surface of the first bonding metal layer may be planarized by performing a planarization process such as chemical mechanical polishing (CMP) to expose the first bonding insulation layer 172, thereby forming the first bonding pads 175 in the first bonding holes. Accordingly, a process with respect to a front side 100a of the first structure 100 may be completed.

In example embodiments, the first bonding pad 175 may be in direct contact with the second horizontal extending portion 152 of the first conductive pad 150a. Because the second horizontal extending portion 152 is directly connected to the first conductive pad 150a by the vertical extending portion 153, the first conductive pad 150a, which is connected to an external terminal (not shown), and the first bonding pad 175, which is connected to a second structure 200, may be directly connected each other, without the need for additional interconnections.

Although not shown in the drawings, a pixel isolation layer (not shown) may be further formed in a back side 100b of the first structure 100. The pixel isolation layer may extend from the back side 101b of the first substrate 101 towards the front side 101a of the first substrate 101. For example, the pixel isolation layer may be formed to surround each of the photodetector 110 to define the plurality of unit pixels.

Referring to FIGS. 2 and 8, a second device layer DL2 corresponding to a logic circuit may be formed over a second substrate 201 to form a second structure 200 (S60). The second substrate 201 may include one or more of silicon, single crystal silicon, germanium, silicon-germanium, or other semiconductor materials similar to the first substrate 101. The second substrate 201 may include a front side 201a and a back side 201b. The second substrate 201 may include a logic circuit region B11 and a second pad region B12. As described above, the logic circuit region B11 may correspond to the pixel array region A11, and the second pad region B12 may correspond to the first pad region A12 while being located on a periphery of the logic circuit region B12.

For example, the second device layer may include a plurality of transistors 210 formed on the front side 201a of the second substrate 201, and a second interconnecting structure 220 formed over the plurality of transistors 210.

The second interconnecting structure 220 may include at least one an interlayer insulating layer 222, a vertical wiring layer 224 in the interlayer insulating layer 222, and a horizontal wiring layer 226 on/under the interlayer insulating layer 222. The vertical wiring layer 224 and horizontal wiring layer 226 may electrically connect the plurality of transistors 210 to form the logic circuit for driving the image elements of the first structure 100. For example, a protective layer 230 may be further formed on the second interconnecting structure 220.

In example embodiments, the plurality of transistors 210 for forming the logic circuit and the second interconnecting structure 220 for connecting the plurality of transistors 210 may be formed over the front side 201a of the second substrate 201 corresponding to the logic circuit region B11. The second interconnecting structure 220 may be formed over the front side 201a of the second substrate 201 corresponding to the second pad region B12.

A second bonding layer 240 may be formed over the second substrate 201 where the second device layer is formed, to form the second structure 200 (S70). The second bonding layer 240 may include a second bonding insulation layer 242, and a plurality of second bonding pads 245 in the second bonding insulation layer 242.

The second bonding insulation layer 242 may include at least one of silicon oxide layer (SiO2), silicon nitride layer (Si3N4), silicon nitride layer (SiON), silicon carbide layer (SiC), and silicon carbon nitride layer (SiCN). The second bonding insulation layer 242 and the protective layer 230 may be etched to expose the uppermost horizontal wiring layer 226 of the second interconnecting structure 220, thereby forming a plurality of second bonding holes (not shown) in the second bonding insulation layer 242 and the protective layer 230. A second bonding metal layer may be formed on the second bonding insulation layer 242 to fill the second bonding holes with the second bonding metal layer. A surface of the second bonding metal layer may be planarized by performing a planarization process such as CMP to expose the second bonding insulation layer 232, thereby forming second bonding pads 235 in the second bonding holes. In this way, the front side 200a of the second structure 200 including the logic circuits (e.g., the second device layer DL2) may be formed. A reference numeral 200b may indicate a back side of the second structure 200, and the back side 200b of the second structure 200 may correspond, for example, to the back side 201b of the second substrate 201.

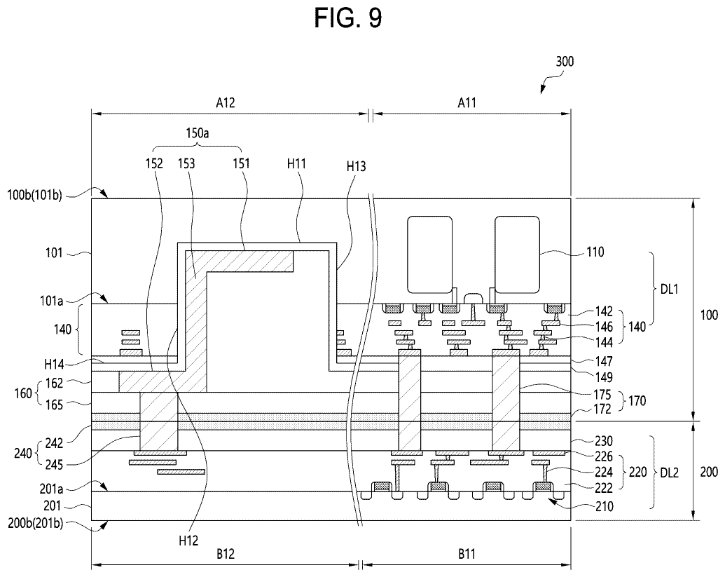

Referring to FIGS. 2 and 9, the first structure 100 and the second structure 200 may be bonded to each other to form a stack type image sensing device 300 (S80).

In example embodiments, the first structure 100 may be stacked on the second structure 200 such that the first bonding layer 170 of the first structure 100 and the second bonding layer 240 of the second structure 200 may face each other.

For example, the first bonding layer 170 and the second bonding layer 230 may be hybrid-bonded to each other. Such a hybrid-bonding process may include: bonding the first and second bonding insulation layers 172 and 242 to each other; and bonding the first and second bonding pads 175 and 245 to each other. In example embodiments, the first and second bonding insulation layers 172 and 242 may be physically bonded through a pressing method. The first and second bonding pads 175 and 245 may be thermally bonded by a low temperature annealing. By bonding the first and second structures 100 and 200, the back side 100b of the first structure 100 (e.g., the back side 101b of the first substrate 101) may be exposed.

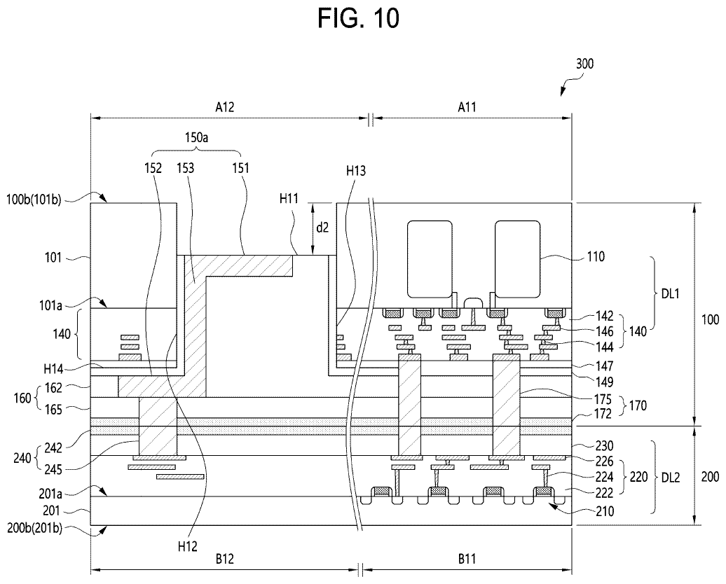

Referring to FIGS. 2 and 10, a pad open region H2 may be formed at the stack type image sensing device (S90).

The pad open region H2 may be formed by etching the back side 101b of the first substrate 101 to the second depth d2 to expose the first conductive pad 150a. As described above, the first horizontal extending portion 151 of the first conductive pad 150a may be positioned in the first substrate 101 by the preliminary open region H1.

Therefore, the first conductive pad 150a, which is used for an electrical connection with an external terminal, may be formed without the need for etching the entire thickness of the first structure 100. For example, the first conductive pad 150a may be formed by etching the second depth d2 (e.g., about 15% to about 60% of the thickness of the first substrate 101) of the first substrate 101, and as a result, the first conductive pad 150a may be exposed.

As such, by forming the first conductive pad 150a in the first substrate 101 of the first structure 100 before bonding the first structure 100 and the second structure 200, an etched amount of the first substrate 101 to form the pad open region H2 or a pad region may be significantly reduced. As a result, defects of the first conductive pad 150a may be prevented.

In an example of a stacked image sensing device, after the first structure and the second structure is bonded, a conductive pad may be formed through the first structure. In this case, since the entire thickness of the first structure should be etched to form the conductive pad, significant damage due to etching may occur in the stacked image sensing device. Furthermore, since the entire thickness of a pad region of the example stack image sensing device greater than the entire thickness of the first structure, an aspect ratio of the pad region may increase, and thus it may be difficult to form the conductive pad with a uniform thickness.

The disclosed technology can be implemented in some embodiments to address these issues. For example, in example embodiments, the first conductive pad 150a in the first substrate 101 is formed before bonding the first structure 100 and the second structure 200, and thus only a portion of the thickness (e.g., the second depth: d2) of the first substrate 101 (not the entire thickness of the first structure 100) may be etched to expose the first conductive pad 150a.

In addition, the first conductive pad 150a based on example embodiments may be configured to directly connect with the first bonding pad 175 of the first structure 100 to reduce a pad resistance of the stack type image sensing device 300.

Referring to FIGS. 1 and 2, an optical assembly may be formed on the stack type image sensing device 300 (S100). The optical assembly may be formed on the back side 100b of the first structure 100. For example, the optical assembly may include a grid structure (not shown), a plurality of color filters (not shown) and a plurality of micro-lenses (ML). The grid structure, the plurality of color filters, and the plurality of micro-lenses (MLs) may be disposed in the pixel array region A11 of the first structure 100.

In example embodiments, before bonding the first structure including the image elements to the second structure including logic circuits, the first conductive pad may be formed in the first structure. The first conductive pad may be formed to extend from the upper surface of the first structure into the first substrate including the first structure. In addition, the bonding pad of the first structure may be formed to be in direct contact with the conductive pad located on the upper surface of the first structure.

By exposing the first conductive pad located in the first substrate after bonding the first structure and the second structure in which the first conductive pad may be formed, the etched amount of the first structure for opening the first conductive pad may be beneficially reduced. Accordingly, the etch damage that would have been caused while exposing the pad may be prevented, and the thickness uniformity of the pad may be improved.

Furthermore, since the first conductive pad formed on the first structure and the bonding pad, in which the hybrid bonding is performed, are in direct contact, the wiring resistance may be reduced.

Only limited examples of implementations or embodiments of the disclosed technology are described or illustrated. Variations and enhancements for the disclosed implementations or embodiments and other implementations or embodiments are possible based on what is disclosed and illustrated in this patent document.

What is claimed is:

1. A method of manufacturing an image sensing device, the method comprising:
stacking a first structure that includes a first substrate, a first device layer, a first conductive pad, a first bonding layer, and a second structure that includes a second substrate, a second device layer, a second bonding layer, by bonding the first bonding layer and the second bonding layer to each other to expose a back side of the first substrate, wherein the first device layer is formed on a front side of the first substrate where the front side and the back side are on two opposite sides of the first substrate, the first conductive pad extends from an upper portion of the first device layer toward the first substrate, and the first bonding layer is formed over the first conductive pad and the first device layer, wherein the second device layer is formed on the second substrate, and the second bonding layer is formed on an upper surface of the second device layer; and
etching the exposed back side of the first substrate by a partial thickness of a thickness of the first substrate to expose the first conductive pad in the first substrate.

2. The method of claim 1, wherein the first structure comprises: a pixel array region including a plurality of photodetectors configured to convert optical images into electrical signals; and a first pad region configured to electrically connect electrical circuits and located at a periphery of the pixel array region, and
wherein the first device layer is formed on the front side of the first substrate corresponding to the first pad region by at least forming, over the front side of the first substrate, a first interconnecting structure that includes including at least one insulating interlayer, at least one horizontal wiring layer formed on a lower or upper surface of the insulating interlayer, and at least one vertical wiring layer connected between horizontal wiring layers.

3. The method of claim 2, wherein the first device layer is formed on the front side of the first substrate corresponding to the pixel array region by:
forming a plurality of photodetectors in the first substrate;
forming a plurality of transfer transistors and a plurality of pixel transistors over the front side of the first substrate; and
forming the first interconnecting structure over the first substrate where the plurality of photodetectors, the plurality of transfer transistors and the plurality of pixel transistors are formed.

4. The method of claim 2, wherein the first conductive pad is formed by at least:
forming, in the first interconnecting structure and the first substrate, a preliminary open region including a bottom portion and first and second sidewall portions extending from edges of the bottom portion by etching the first interconnecting structure and the first substrate in the first pad region to a first depth;
forming a pad metal layer in the preliminary open region and on the first interconnecting structure; and
etching a selected portion of the pad metal layer to form the first conductive pad on the bottom portion of the preliminary open region, the first sidewall portion of the preliminary open region, and an outer portion of the preliminary open region connected to the first sidewall portion of the preliminary opening region.

5. The method of claim 4, wherein forming the preliminary open region comprises:
forming a mask pattern over the first interconnecting structure;
etching the first interconnecting structure using the mask pattern to expose the front side of the first substrate;
etching the exposed front side of the first substrate to the first depth; and
removing the mask pattern,
wherein the first depth ranges from about 40% to about 85% of a thickness of the first substrate.

6. The method of claim 4, wherein forming the first bonding layer comprises:
forming a first bonding insulation layer on the first conductive pad and the first interconnecting structure;
etching a selected portion of the first bonding insulation layer to form a plurality of first bonding holes in the first bonding insulation layer; and
forming a metal layer in the plurality of first bonding holes to form a plurality of first bonding pads,
wherein at least one of the plurality of first bonding holes is formed to expose the first conductive pad on the first interconnecting structure in the first pad region.

7. The method of claim 6, wherein the second structure further comprises: a logic circuit region corresponding to the pixel array region; and a second pad region located on a periphery of the logic circuit region,
wherein the second device layer included in the second structure is formed by at least:
forming a plurality of transistors on the second substrate corresponding to at least one of the logic circuit region and the second pad region; and
forming, over the second substrate that includes the plurality of transistors, a second interconnecting structure that includes at least one insulating interlayer, at least one horizontal wiring layer formed on a lower or upper surface of the insulating interlayer, and at least one vertical wiring layer connected between the horizontal wiring layers.

8. The method of claim 7, wherein the second bonding layer is formed by at least:
forming a second bonding insulation layer on the second interconnecting structure;
etching the second bonding insulation layer until uppermost horizontal wiring layers of the second interconnecting structure is exposed to form a plurality of second bonding holes in the second bonding insulation layer; and
forming a metal layer in the plurality of second bonding holes to form a plurality of second bonding pads bonded to the first bonding pads.

9. A method of manufacturing an image sensing device, the method comprising:
forming a first device layer on a front side of a first substrate which includes a back side that is opposite to the front side;
forming a preliminary open region in the first device layer and the first substrate;
forming a first conductive pad on a bottom portion of the preliminary open region in the first substrate, a first sidewall portion connected to the bottom portion, and an outer portion of the preliminary open region connected with the first sidewall portion;
forming a first bonding layer including a first bonding pad in contact with the first conductive pad located on the first device layer;
forming a second device layer, and a second bonding layer that includes a second bonding pad corresponding to the first bonding pad that are sequentially stacked on a second substrate;
bonding the first bonding layer to the second bonding layer to bond the first substrate to the second substrate; and
etching the back side of the first substrate to expose the first conductive pad located at the bottom portion of the preliminary open region while bonding the first substrate and the second substrate to each other.

10. The method of claim 9, wherein the first substrate comprises a first region and a second region,
wherein forming the first device layer comprises:
forming an image element on the front side of the first substrate corresponding to the first region; and
forming a first interconnecting structure on the front side of the first substrate corresponding to the first region and the second region that include the image element to define a pixel array in the first region.

11. The method of claim 10, wherein forming the preliminary open region comprises:
forming a mask pattern on the first interconnecting structure in the second region;
etching the first interconnecting structure using a mask pattern to expose the front side of the first substrate;
etching the exposed front side of the first substrate to a first depth using the mask pattern, wherein the preliminary open region includes a bottom portion and sidewall portions extending from edges of the bottom portion to an upper surface of the first interconnecting structure; and
removing the mask pattern.

12. The method of claim 11, wherein the first depth is 40% to 85% of a depth or thickness of the first substrate.

13. The method of claim 12, wherein etching the back side of the first substrate to expose the first conductive pad comprises etching the back side of the first substrate by 15% to 60% of a thickness of the first substrate.

14. The method of claim 9, wherein the second substrate comprises a third region and a fourth region, and
wherein the second device layer is formed by at least:
forming a plurality of transistors on the front side of the second substrate corresponding to at least one of the third and fourth regions; and
forming a second interconnecting structure on the third and fourth regions to electrically connect the plurality of transistors with each other to form a logic circuit configured to operate a pixel array.

15. The method of claim 14, wherein forming the second bonding layer comprises:
forming a second bonding insulation layer over the second interconnecting structure; and
forming a plurality of second bonding pads electrically coupled to at least one wiring layer of the second interconnecting structure, in the second bonding insulating layer.

16. A stack type image sensing device comprising:
a first structure including a first substrate, an image device layer formed under the first substrate, and a first bonding layer including a plurality of first bonding pads under the image device layer;
a second structure including a second bonding layer including a plurality of second bonding pads bonded to the plurality of first bonding pads of the first structure, a logic circuit layer positioned under the second bonding layer, and a second substrate positioned under the logic circuit layer; and
a first conductive pad including a first horizontal extending portion spaced apart from a front side of the first substrate to a selected depth, a vertical extending portion extending from the first horizontal extending portion to a lower surface of the image device layer, and a second horizontal extending portion extending from the vertical extending portion by a set length along a lower surface of the image device layer, wherein the second horizontal extending portion of the first conductive pad is in contact with a selected first bonding pad that is selected from the plurality of first bonding pads.

17. The stack type image sensing device of claim 16, wherein the selected depth ranges from 15% to 60% of a thickness of the first substrate.

18. The stack type image sensing device of claim 16, wherein the first horizontal extending portion extends in a first horizontal direction parallel to a back side of the first substrate, and the second horizontal extending portion extends in a second horizontal direction opposite to the first horizontal direction.

19. The stack type image sensing device of claim 16, wherein the second horizontal extending portion of the first conductive pad, the first bonding pad and the second bonding pad are in direct contact.
